(19) United States
(12) Patent Application Publication
(10) Pub. No.: US 2024/0120184 A1
(43) Pub. Date: Apr. 11, 2024

(54) SUBSTRATE PROCESSING APPARATUS

(71) Applicant: Tokyo Electron Limited, Tokyo (JP)

(72) Inventor: Ryosuke GUNJI, Miyagi (JP)

(21) Appl. No.: 18/372,995

(22) Filed: Sep. 26, 2023

(30) Foreign Application Priority Data
Sep. 29, 2022 (JP) 2022-155947

(51) Int. Cl. H01J 37/32

(52) U.S. Cl. CPC H01J 37/32834; H01J 2237/332

(57) ABSTRACT

A substrate processing apparatus includes a chamber comprising an exhaust port in a bottom portion of the chamber, a substrate support disposed within the chamber, a partition member that partitions a substrate processing region from an exhaust region connected to the exhaust port, one or more plate-shaped members provided upstream of the partition member with respect to a flow of exhaust gas to the exhaust port and configured to block particles from the partition member. At least one of the one or more plate-shaped members comprises a through-hole configured to allow the exhaust gas to the exhaust port to pass therethrough, the through-hole opened to be directed to a side surface of the substrate support or to an inner surface of the chamber.

### CROSS-REFERENCE TO RELATED APPLICATION

This application is based upon and claims the benefit of priority from Japanese Patent Application No. 2022-155947, filed on Sep. 29, 2022, the entire contents of which are incorporated herein by reference.

### TECHNICAL FIELD

The present disclosure relates to a substrate processing apparatus.

### BACKGROUND

In a plasma processing apparatus, for example, an annular exhaust flow path configured to exhaust a processing gas to the exterior of a chamber is provided around a substrate support that supports a substrate to be processed. In addition, a baffle plate (hereinafter, also referred to as a “partition member”) configured to adjust the flow of the processing gas is provided in the exhaust flow path. The baffle plate is provided with through-holes through which the processing gas passes (Patent Document 1).

### PRIOR ART DOCUMENT

[Patent Document]
Patent Document 1: U.S. Patent Application Publication No. 2015/0262794

### SUMMARY

According to one embodiment of the present disclosure, there is provided a substrate processing apparatus including a chamber comprising an exhaust port in a bottom portion of the chamber, a substrate support disposed within the chamber, a partition member that partitions a substrate processing region from an exhaust region connected to the exhaust port, one or more plate-shaped members provided upstream of the partition member with respect to a flow of exhaust gas to the exhaust port and configured to block particles from the partition member, wherein at least one of the one or more plate-shaped members comprises a through-hole configured to allow the exhaust gas to the exhaust port to pass therethrough, the through-hole opened to be directed to a side surface of the substrate support or to an inner surface of the chamber.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram illustrating an example of a plasma processing system according to an embodiment of the present disclosure.

FIG. 2 is a view illustrating an example of a plasma processing apparatus according to an embodiment.

FIG. 3 is a partially enlarged view illustrating an example of a cross section near a baffle plate according to an embodiment.

FIG. 4 is an explanatory view illustrating an example of a shielding mechanism by plate-shaped members.

FIG. 5 is an explanatory view illustrating an example of a shielding effect by a through-hole.

FIG. 6 is an explanatory view illustrating an example of an angle of a through-hole at which shielding is possible.

FIG. 7 is an explanatory view illustrating an example of an angle of a through-hole at which shielding is possible.

FIG. 8 is an explanatory view illustrating an example of the relationship between the dimension and the angle of a through-hole.

FIG. 9 is an explanatory view illustrating an example of the relationship between the dimension and the angle of a through-hole.

FIG. 10 is an explanatory view illustrating an example of angles that through-holes can take.

FIG. 11 is a view illustrating an example of a combination of arrangement of plate-shaped members and through-holes in Example.

FIG. 12 is a view illustrating an example of a combination of arrangement of plate-shaped members and through-holes in Modification 1.

FIG. 13 is a view illustrating an example of a combination of arrangement of plate-shaped members and through-holes in Modification 2.

FIG. 14 is a view illustrating an example of a combination of arrangement of plate-shaped members and through-holes in Modification 3.

FIG. 15 is a view illustrating an example of a combination of arrangement of plate-shaped members and through-holes in Modification 4.

FIG. 16 is a view illustrating an example of a combination of arrangement of plate-shaped members and through-holes in Modification 5.

FIG. 17 is a view illustrating an example of a combination of arrangement of plate-shaped members and through-holes in Modification 6.

FIG. 18 is a view illustrating an example of a combination of arrangement of plate-shaped members and through-holes in Modification 7.

FIG. 19 is a view illustrating an example of a combination of arrangement of plate-shaped members and through-holes in Modification 8.

FIG. 20 is a view illustrating an example of a combination of arrangement of plate-shaped members and through-holes in Modification 9.

FIG. 21 is a view illustrating an example of an arrangement of through-holes in Modification 9 when viewed in a vertical direction.

FIGS. 22 to 25 illustrate Equations 1 to 4, respectively.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of a substrate processing apparatus according to the present disclosure will be described in detail based on the drawings. The technology disclosed herein is not limited by the following embodiments.

As described above, in a plasma processing apparatus, since a baffle plate is located near a boundary between a plasma processing space and an exhaust flow path, ions and radicals generated by plasma may collide with the baffle and particles may be generated. When the generated particles adhere to a substrate to be processed in the plasma processing space, lack of contacts, inter-element connection, and the like occur due to poor etching. Therefore, as a countermeasure against particles generated from a lower portion of a chamber, such as the baffle plate, it is conceivable to place a plate-shaped member above the baffle plate to block the particles. However, when the area of the plate-shaped member is increased or when a plurality of plate-shaped members are overlapped in order to improve a particle shielding effect, conductance during exhaust from the interior of the chamber deteriorates. That is, the exhaust characteristics are degraded. When the conductance deteriorates, the operating ranges of pressure, the flow rate of the processing gas, and the like become narrow for the condition of a low pressure and a high flow rate, so that it may become difficult to process a substrate under appropriate conditions. Therefore, it is expected to suppress the deterioration of exhaust characteristics while suppressing particles generated by a partition member (the baffle plate) from flying to the substrate.

### [Configuration of Plasma Processing System]

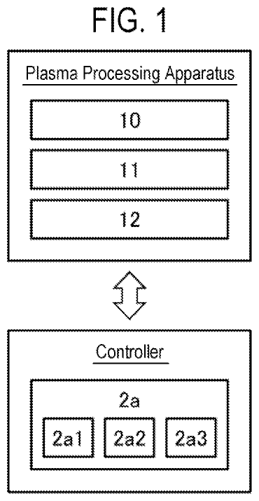

FIG. 1 is a diagram illustrating an example of a plasma processing system according to an embodiment of the present disclosure. In an embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 includes a plasma processing space. In addition, the plasma processing chamber 10 includes at least one gas supply port configured to supply at least one processing gas to the plasma processing space, and at least one gas discharge port configured to discharge gas from the plasma processing space. The gas supply port is connected to a gas supplier 20 to be described later, and the gas discharge port is connected to an exhaust system 40 to be described later. The substrate support 11 is arranged in the plasma processing space and has a substrate support surface for supporting a substrate.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance (ECR) plasma, helicon wave plasma (HWP), surface wave plasma (SWP), or the like. In addition, various types of plasma generators including an alternating current (AC) plasma generator and a direct current (DC) plasma generator may be used. In an embodiment, an AC signal (AC power) used in the AC plasma generator has a frequency in the range of 100 kHz to 10 GHz. Therefore, the AC signal includes a radio-frequency (RF) signal and a microwave signal. In an embodiment, the RF signal has a frequency in the range of 100 kHz to 150 MHz.

The controller 2 processes computer-executable commands that cause the plasma processing apparatus 1 to execute various processes described in the present disclosure. The controller 2 may be configured to control each element of the plasma processing apparatus 1 to perform various processes described herein. In an embodiment, a part or all of the controller 2 may be included in the plasma processing apparatus 1. The controller 2 may include a processor 2a1, a storage 2a2, and a communication interface 2a3. The controller 2 is implemented by, for example, a computer 2a. The processor 2a1 may be configured to perform various control operations by reading a program from the storage 2a2 and executing the read program. This program may be stored in the storage 2a2 in advance, or may be acquired via a medium when necessary. The acquired program is stored in the storage 2a2, and read from the storage 2a2 and executed by the processor 2a1. The medium may be various storage media readable by the computer 2a, or may be a communication line connected to the communication interface 2a3. The processor 2a1 may be a central processing unit (CPU). The storage 2a2 may include a non-transitory computer readable storage medium such as random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

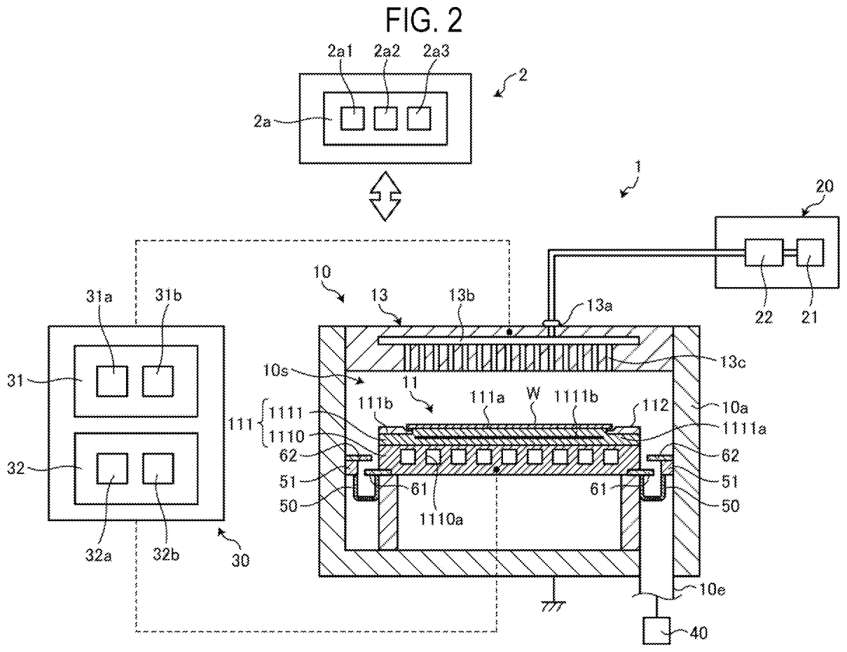

A configuration example of a capacitively coupled plasma processing apparatus as an example of the plasma processing apparatus 1 will be described below. FIG. 2 is a view illustrating an example of a plasma processing apparatus according to the present embodiment.

A capacitively coupled plasma processing apparatus 1 includes a plasma processing chamber 10, a gas supplier 20, a power supply 30, and an exhaust system 40. In addition, the plasma processing apparatus 1 includes a substrate support 11 and a gas introducer. The gas introducer is configured to introduce at least one processing gas into the plasma processing chamber 10. The gas introducer includes a shower head 13. The substrate support 11 is arranged in the plasma processing chamber 10. The shower head 13 is arranged above the substrate support 11. In an embodiment, the shower head 13 constitutes at least a portion of the ceiling of the plasma processing chamber 10. The plasma processing chamber 10 includes a plasma processing space 10s defined by the shower head 13, the side wall 10a of the plasma processing chamber 10, and the substrate support 11. The plasma processing chamber 10 is grounded. The shower head 13 and the substrate support 11 are electrically insulated from the housing of the plasma processing chamber 10.

The substrate support 11 includes a main body 111 and a ring assembly 112. The main body 111 includes a central region 111a configured to support a substrate W and an annular region 111b configured to support the ring assembly 112. A wafer is an example of a substrate W. The annular region 111b of the main body 111 surrounds the central region 111a of the main body 111 in plan view. The substrate W is placed on the central region 111a of the main body 111, and the ring assembly 112 is disposed on the annular region 111b of the main body 111 to surround the substrate W on the central region 111a of the main body 111. Accordingly, the central region 111a is also referred to as a “substrate support surface” configured to support the substrate W, and the annular region 111b is also referred to as a “ring support surface” configured to support the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed inside the ceramic member 1111a. The ceramic member 1111a has a central region 111a. In an embodiment, the ceramic member 1111a also has an annular region 111b. Another member surrounding the electrostatic chuck 1111, such as an annular electrostatic chuck or an annular insulating member, may have the annular region 111b. In this case, the ring assembly 112 may be placed on the annular electrostatic chuck or the annular insulating member, or may be placed on both the electrostatic chuck 1111 and the annular insulating member. In addition, at least one RF/DC electrode coupled to an RF power supply 31 and/or a DC power supply 32 to be described below, may be disposed within the ceramic member 1111a. In this case, at least one RF/DC electrode functions as the lower electrode. When a bias RF signal and/or a DC signal to be described below is applied to at least one RF/DC electrode, the RF/DC electrode is also called a “bias electrode”. In addition, the conductive member of the base 1110 and at least one RF/DC electrode may function as a plurality of lower electrodes. In addition, the electrostatic electrode 1111b may function as a lower electrode. Accordingly, the substrate support 11 includes at least one lower electrode.

The ring assembly 112 includes one or more annular members. In an embodiment, the one or more annular members include one or more edge rings and at least one cover ring. The edge rings are made of a conductive material or an insulating material, and the cover ring is made of an insulating material.

In addition, the substrate support 11 may include a temperature adjusting module configured to adjust at least one of the electrostatic chuck 1111, the ring assembly 112, and the substrate to a target temperature. The temperature adjusting module may include a heater, a heat transfer media, a flow path 1110a, or a combination thereof. A heat transfer fluid, such as brine or gas, flows through the flow path 1110a. In an embodiment, the flow path 1110a is formed in the base 1110, and one or more heaters are disposed in the ceramic member 1111a of electrostatic chuck 1111. The substrate support 11 may also include a heat transfer gas supplier configured to supply a heat transfer gas to the gap between the rear surface of the substrate W and the central region 111a.

The shower head 13 is configured to introduce at least one processing gas from the gas supplier 20 into the plasma processing space 10s. The shower head 13 includes at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. In addition, the shower head 13 includes at least one upper electrode. In addition to the shower head 13, the gas introducer may include one or more side gas injectors (SGIs) installed in one or more openings formed in the side wall 10a.

The gas supplier 20 may include at least one gas source 21 and at least one flow rate controller 22. In an embodiment, the gas supplier 20 is configured to supply at least one processing gas from a corresponding gas source 21 to the shower head 13 via the corresponding flow rate controller 22. Each flow rate controller 22 may include, for example, a mass flow controller or a pressure-controlled flow rate controller. The gas supplier 20 may include at least one flow rate modulation device configured to modulate or pulse the flow rate of the at least one processing gas.

The power supply 30 includes an RF power supply 31 coupled to the plasma processing chamber 10 via at least one impedance matching circuit. The RF power supply 31 is configured to supply at least one RF signal (RF power) to the at least one lower electrode and/or the at least one upper electrode. As a result, plasma is formed from the at least one processing gas supplied to the plasma processing space 10s. Therefore, the RF power supply 31 can function as at least a portion of the plasma generator 12. In addition, by supplying a bias RF signal to the at least one lower electrode, a bias potential is generated in the substrate W, and an ionic component in the formed plasma can be drawn into the substrate W.

In an embodiment, the RF power supply 31 includes a first RF generator 31a and a second RF generator 31b. The first RF generator 31a is coupled to the at least one lower electrode and/or the at least one upper electrode via at least one impedance matching circuit to generate a source RF signal (source RF power) for plasma generation. In another embodiment, the source RF signal has a frequency in the range of 10 MHz to 150 MHz. In an embodiment, the first RF generator 31a may be configured to generate a plurality of source RF signals having different frequencies. One or more generated source RF signals are provided to the at least one lower electrode and/or the at least one upper electrode.

A second RF generator 31b is coupled to the at least one lower electrode via at least one impedance matching circuit and is configured to generate a bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency in the range of 100 kHz to 60 MHz. In an embodiment, the second RF generator 31b may be configured to generate a plurality of bias RF signals having different frequencies. One or more generated bias RF signals are provided to at least one lower electrode. In addition, in various embodiments, at least one of the source RF signal and the bias RF signal may be pulsed.

The power supply 30 may include a DC power supply 32 coupled to the plasma processing chamber 10. The DC power supply 32 includes a first DC generator 32a and a second DC generator 32b. In an embodiment, the first DC generator 32a is connected to the at least one lower electrode and is configured to generate a first DC signal. The generated first DC signal is applied to the at least one lower electrode. In an embodiment, the second DC generator 32b is connected to the at least one upper electrode and is configured to generate a second DC signal. The generated second DC signal is applied to the at least one upper electrode.

In various embodiments, the first and second DC signals may be pulsed. In this case, a sequence of voltage pulses is applied to the at least one lower electrode and/or the at least one upper electrode. The voltage pulses may have a rectangular pulse waveform, a trapezoidal pulse waveform, a triangular pulse waveform, or a combination thereof. In an embodiment, a waveform generator configured to generate a sequence of voltage pulses from a DC signal is connected between the first DC generator 32a and the at least one lower electrode. Therefore, the first DC generator 32a and the waveform generator constitute a voltage pulse generator. When the second DC generator 32b and the waveform generator constitute a voltage pulse generator, the voltage pulse generator is connected to at least one upper electrode. The voltage pulse may have a positive polarity or a negative polarity. In addition, the sequence of voltage pulses may include one or more positive voltage pulses and one or more negative voltage pulses in one cycle. The first and second DC generators 32a and 32b may be provided in addition to the RF power supply 31, or the first DC generator 32a may be provided in place of the second RF generator 31b.

The exhaust system 40 may be connected to, for example, a gas discharge port 10e provided in the bottom portion of the plasma processing chamber 10. The exhaust system 40 may include a pressure adjusting valve and a vacuum pump. By the pressure adjusting valve, the pressure in the plasma processing space 10s is adjusted. The vacuum pump may include a turbo molecular pump, a dry pump, or a combination thereof.

A baffle plate 50 partitions between the plasma processing space 10s and the gas discharge port 10e. The baffle plate 50 is disposed between the side wall of the main body 111 and a support member 51 of the side wall 10a. That is, the baffle plate 50 is an example of a partition member that partitions the interior of the plasma processing chamber 10 into the plasma processing space 10s, which is a processing region for substrate processing, and an exhaust region, which is connected to the gas discharge port 10e. The baffle plate 50 is made of, for example, iron or aluminum, and has a thermally sprayed film of yttria or the like formed on the surface thereof. The baffle plate 50 is provided with a plurality of through-holes for exhaust.

A first plate-shaped member 61 and a second plate-shaped member 62 for blocking particles generated from the lower portion of the plasma processing chamber 10 are disposed on the baffle plate 50 on the plasma processing space 10s side. The first plate-shaped member 61 and the second plate-shaped member 62 are formed in an annular shape to surround the substrate support 11. The first plate-shaped member 61 and the second plate-shaped member 62 block the flight paths of particles coming directly from the baffle plate 50 or particles coming after a first reflection, when viewed from the substrate W. The first plate-shaped member 61 and the second plate-shaped member 62 are made of, for example, quartz, silicon, or the like. At least one of the first plate-shaped member 61 and the second plate-shaped member 62 is provided with through-holes that secure conductance at the time of exhaust of the gas from the plasma processing chamber 10 and are formed to be directed to other members other than the substrate W located in the processing region.

### [Layout of Plate-Shaped Members]

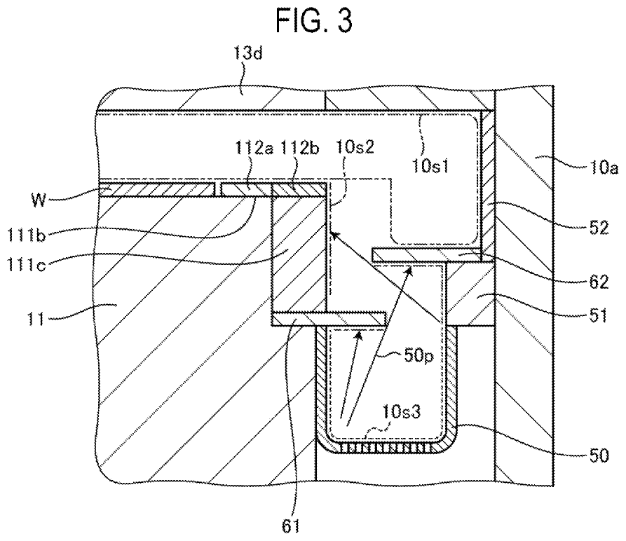

FIG. 3 is a partially enlarged view illustrating an example of a cross section near the baffle plate in the present embodiment. As illustrated in FIG. 3, the shield member 111c and the first plate-shaped member 61 are disposed on the side wall of the substrate support 11.

The shield member 111c is made of, for example, quartz, silicon, or the like. The ring assembly 112 disposed in the annular region 111b includes an edge ring 112a and a cover ring 112b. The cover ring 112b is disposed on the shield member 111c, which constitutes a portion of the annular region 111b, and constitutes the side surface of the substrate support 11 together with the shield member 111c. The edge ring 112a is made of a conductive material or an insulating material such as silicon or quartz. In addition, the cover ring 112b is made of, for example, an insulating material, such as quartz.

The first plate-shaped member 61 is disposed to provide a gap with respect to the support member 51 on the side wall 10a side. On the other hand, the second plate-shaped member 62 is disposed above the support member 51 on the side wall 10a side. The second plate-shaped member 62 is disposed to provide a gap with respect to the shield member 111c on the substrate support 11 side. That is, the first plate-shaped member 61 and the second plate-shaped member 62 are arranged alternately. The gap between the first plate-shaped member 61 and the support member 51 and the gap between the second plate-shaped member 62 and the shield member 111c serve as a flow path for the processing gas being exhausted. A coating film 52 made of, for example, quartz or silicon is formed on the inner peripheral surface of the side wall 10a above the second plate-shaped member 62. In addition, the support member 51 is made of, for example, quartz, silicon, or the like.

The region 10s1 illustrated in FIG. 3 is a region in which, among particles generated from the lower portion of the plasma processing chamber 10, particles coming directly or after a first reflection when viewed from the substrate W are not present. The region 10s1 generally includes the space between the upper electrode 13d of the showerhead 13 and the substrate W, and the space surrounded by the peripheral edge of the shower head 13, the coating film 52, and the top surface of the second plate-shaped member 62.

The region 10s2 is a region that traps particles generated from the lower portion of the plasma processing chamber 10 by reflecting the particles at least once on the wall surface. The region 10s2 is generally surrounded by the side surface of the shield member 111c, the side surface of the cover ring 112b, the top surface of the first plate-shaped member 61, the side surface of the support member 51, and the bottom surface of the second plate-shaped member 62. The region 10s2 also includes the bottom surface and side surface of the first plate-shaped member 61. In FIG. 3, as part of the range of the region 10s2, the wall surfaces on which the generated particles collide for the first time are mainly illustrated.

The region 10s3 is a region in which particles are generated in the lower portion of the plasma processing chamber 10. The region 10s3 is surrounded by the surface of the baffle plate 50. In the region 10s3, ions and radicals collide with the thermally sprayed film of the baffle plate 50, and particles containing yttrium of the thermally sprayed film and iron, aluminum, and the like of the base layer are generated. In FIG. 3, the flight paths of particles generated in the region 10s3 are represented as paths 50p.

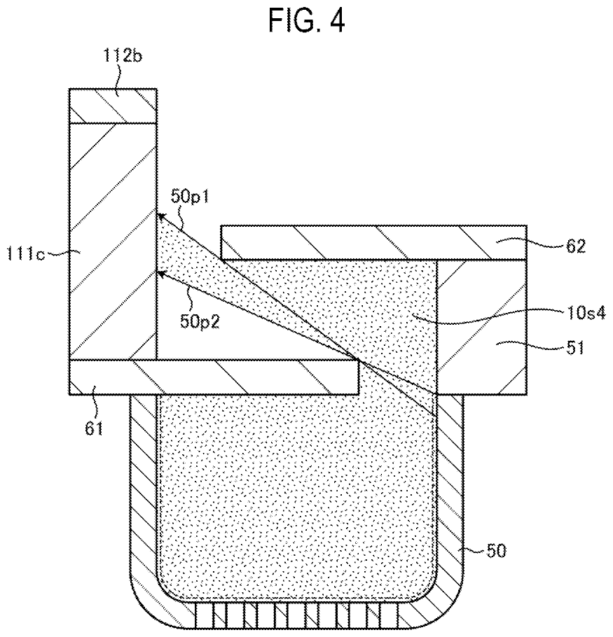

Here, a particle shielding mechanism by the plate-shaped members will be described with reference to FIG. 4. FIG. 4 is an explanatory view illustrating an example of a shielding mechanism by plate-shaped members. The particle region 10s4 illustrated in FIG. 4 indicates a region directly hit by the particles generated in the region 10s3 illustrated in FIG. 3. When the first plate-shaped member 61 and the second plate-shaped member 62 illustrated in FIG. 4 are not provided with through-holes, the particles are 100% blocked by the first plate-shaped member 61 and the second plate-shaped member 62. Particles flying to the uppermost portion include particles in the range surrounded by the path 50p1 and the path 50p2. However, even if the particles are reflected by the shield member 111c, the particles fly to the side wall 10a of the plasma processing chamber 10, so the particles do not reach the substrate W by one reflection. However, when the first plate-shaped member 61 and the second plate-shaped member 62 are not provided with through-holes, the amount of overlap between the first plate-shaped member 61 and the second plate-shaped member 62 increases, and exhaust conductance deteriorates. Accordingly, in the present embodiment, exhaust conductance is improved by providing through-holes in at least one of the first plate-shaped member 61 and the second plate-shaped member 62.

### [Details of Through-Holes]

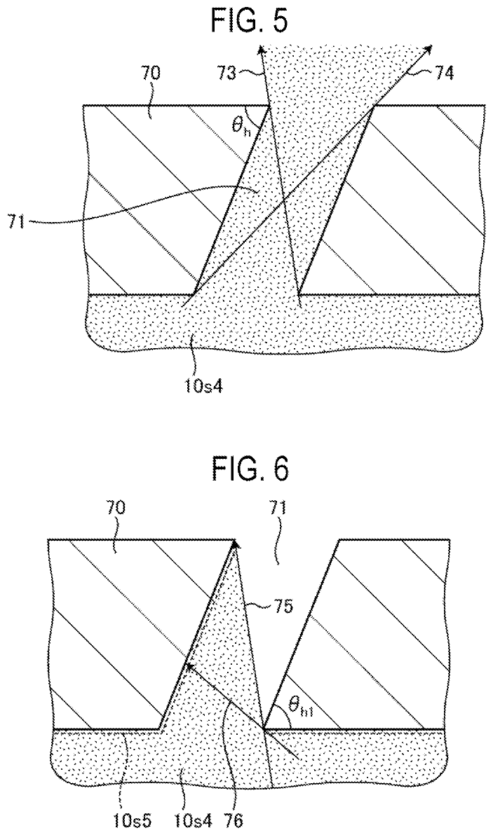

Next, the details of through-holes will be described with reference to FIGS. 5 to 10. FIG. 5 is an explanatory view illustrating an example of a shielding effect by a through-hole. As illustrated in FIG. 5, when a circular through-hole 71 having an angle θₕ is provided in the plate-shaped member 70, the range in which particles from the particle region 10s4 pass through the through-hole 71 is a range of the incident angle between lines 73 and 74. That is, it is possible to block particles incident at angles other than an incident angle between lines 73 and 74. The particles passing through the through-hole 71 can also be reduced by reducing the diameter of the through-hole 71 or increasing the thickness of the plate-shaped member 70.

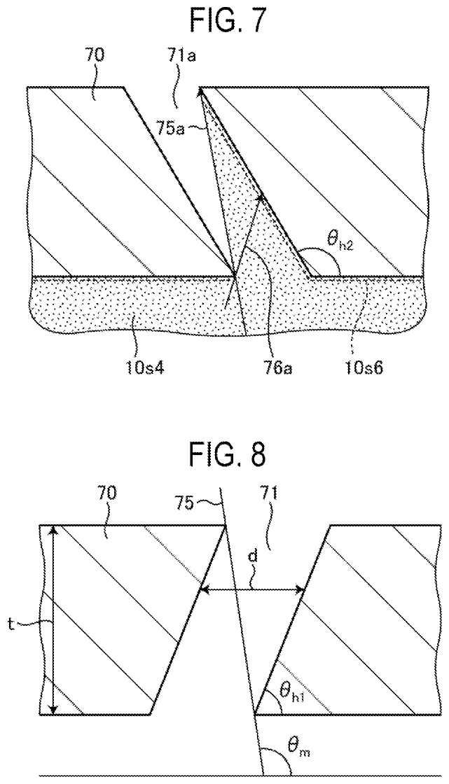

FIGS. 6 and 7 are explanatory views illustrating examples of angles of through-holes at which shielding is possible. FIG. 6 illustrates a case where the through-hole 71 having an angle θₕ₁ blocks particles having an incident angle larger than a blocking limit angle indicated by line 75. For example, particles having an incident angle indicated by line 76 hit the inner wall of the through-hole 71 and are trapped. The trapping region 10s5 represents a region where particles having an incident angle larger than the blocking limit angle indicated by line 75 are trapped on the inner wall of the through-hole 71 and a region in which particles are trapped on the bottom surface of the plate-shaped member 70.

FIG. 7 illustrates a case where a through-hole 71a having an angle θₕ₂ blocks particles having an incident angle smaller than a blocking limit angle indicated by line 75a. For example, particles having an incident angle indicated by line 76a hit the inner wall of the through-hole 71a and are trapped. The trapping region 10s6 represents a region where particles having an incident angle smaller than the blocking limit angle indicated by line 75a are trapped on the inner wall of the through-hole 71a and a region in which particles are trapped on the bottom surface of the plate-shaped member 70.

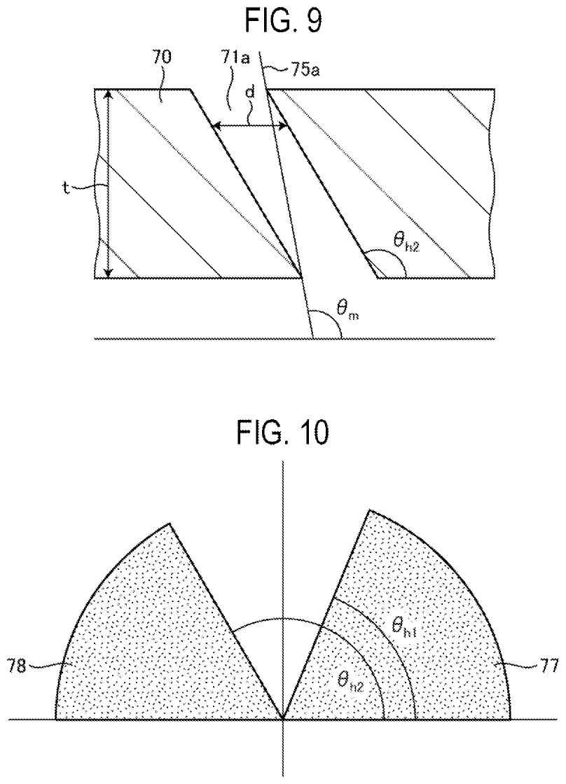

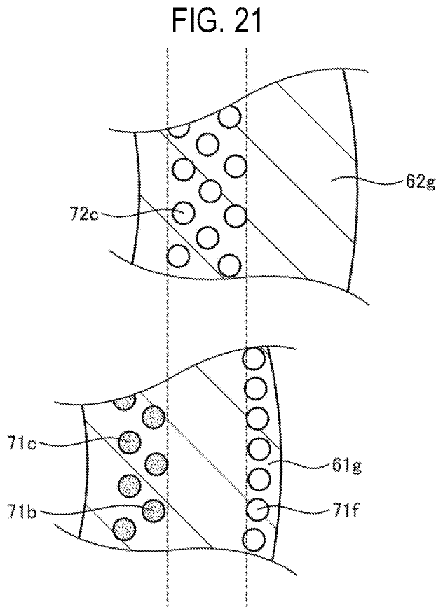

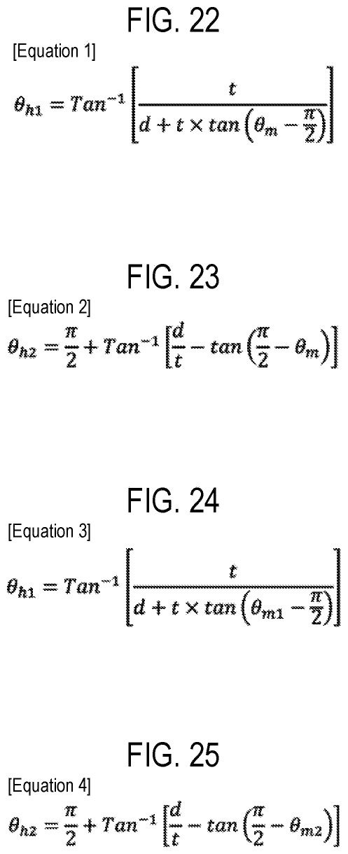

FIGS. 8 and 9 are explanatory views illustrating examples of the relationship between the dimension and the angle of the through-hole. FIG. 8 illustrates the relationship between the dimension and the angle of the through-hole 71 which is inclined to an acute angle side (angle θₕ₁ side). In FIG. 8, when the thickness of the plate-shaped member 70 is t, the diameter of the through-hole 71 is d, and the maximum required shielding angle is θₘ, a limit hole angle θₕ₁, which represents the limit of the angle of the through-hole 71, may be expressed by Equation 1 shown in FIG. 22. In addition, the limit hole angle θₕ₁ Corresponds to the angle θₕ₁ in FIG. 6.

Here, the maximum required shielding angle θₘ is an angle formed between a horizontal plane and a line 75 interconnecting a position where the through-hole 71 is provided in the surface of the plate-shaped member 70 and a limit point where the particles passing through the through-hole 71 do not fall on the substrate W directly or after a first reflection. For example, the maximum required shielding angle is an angle that is formed between the horizontal plane and the line interconnecting the upper end portion of the cover ring 112b, which is the uppermost portion of the region 10s2 illustrated in FIG. 3, and the position where the through-hole is provided in the first plate-shaped member 61. The maximum required shielding angle θₘ in FIG. 8 is an example of the angle θₘ₁. In addition, the limit hole angle θₕ₁ is the acute angle of the two angles at which shielding is possible with respect to the maximum required shielding angle θₘ. That is, the through-hole 71 is provided at an angle equal to or smaller than the limit hole angle θₕ₁.

FIG. 9 illustrates the relationship between the dimension and the angle of a through-hole 71a which is inclined to the obtuse angle side (angle θₕ₂ side). In FIG. 9, when the thickness of the plate-shaped member 70 is t, the diameter of the through-hole 71a is d, and the maximum required shielding angle is θₘ, a limit hole angle θₕ₂ representing the limit of the angle of the through-hole 71a may be expressed by the Equation 2 shown in FIG. 23. In addition, the limit hole angle θₕ₂ corresponds to the angle θₕ₂ in FIG. 7.

Here, the maximum required shielding angle θₘ is an angle formed between the horizontal plane and the line 75a interconnecting the position where the through-hole 71a is provided in the surface of the plate-shaped member 70 and the limit point where the particles passing through the through-hole 71a do not fall on the substrate W directly or after a first reflection. The maximum required shielding angle θₘ in FIG. 9 is an example of the angle θₘ₂. In addition, the limit hole angle θₕ₂ is the obtuse angle of the two angles at which shielding is possible with respect to the maximum required shielding angle θₘ. That is, the through-hole 71a is provided at an angle equal to or larger than the limit hole angle θₕ₂.

FIG. 10 is an explanatory view illustrating an example of angles that through-holes can take. FIG. 10 summarizes possible angles of the through-holes 71 and 71a based on the limit hole angles θₕ₁ and θₕ₂ illustrated in FIGS. 8 and 9. As illustrated in FIG. 10, the range 77 from 0 degrees to the limit hole angle θₕ₁ and the range 78 from the limit hole angle θₕ₂ to 180 degrees are the possible angle ranges of the through-holes 71 and 71a. That is, the through-holes 71 and 71a can block particles to be fallen on the substrate W directly or after a first reflection if the angles of the through-holes are within the ranges 77 and 78, respectively.

### [Arrangement of Plate-Shaped Members and Through-Holes]

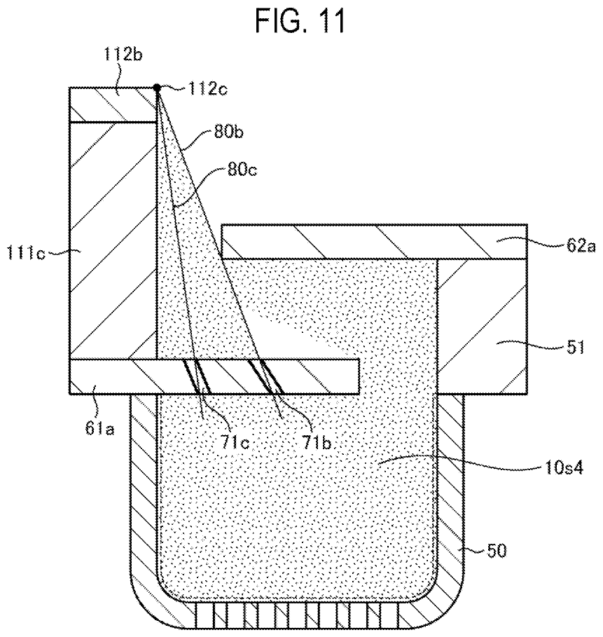

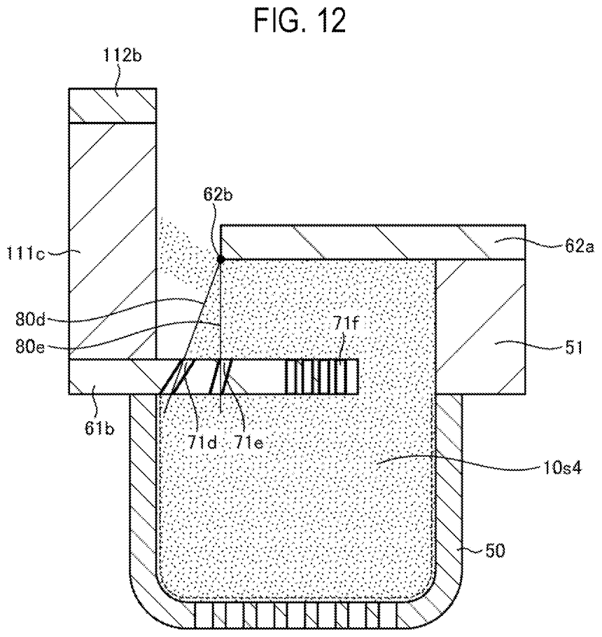

Next, with reference to FIG. 11, an arrangement of plate-shaped members and through-holes will be described. FIG. 11 is a view illustrating an example of a combination of arrangement of plate-shaped members and through-holes in Example. FIG. 11 illustrates a case where a first plate-shaped member 61a, which is obtained by providing through-holes in the first plate-shaped member 61, and a second plate-shaped member 62a, which is not provided with through-holes, are combined.

First, a method of calculating the angles of through-holes provided in the first plate-shaped member 61a will be described. In FIG. 11, the particles passing through the through-holes of the first plate-shaped member 61a are trapped by side walls of the shield member 111c and the cover ring 112b. In this case, since the through-holes are directed to the substrate support 11 side, the angles of the through-holes are set to be equal to or larger than the limit hole angle θₕ₂. Next, the maximum required shielding angle θₘ, which is the angle of a line interconnecting the position of a through-hole in the first plate-shaped member 61a and the upper end portion 112c of the cover ring 112b, is calculated. Regarding the through-hole 71b, the angle of line 80b interconnecting the position of the through-hole 71b and the upper end portion 112c of the cover ring 112b is defined as the maximum required shielding angle θₘ and is set to an angle equal to or larger than the limit hole angle θₕ₂ calculated based on the above-described Equation 2. Similarly, regarding the through-hole 71c, the angle of line 80c interconnecting the position of the through-hole 71c and the upper end portion 112c of the cover ring 112b is defined as the maximum required shielding angle θₘ and is set to an angle equal to or larger than the limit hole angle θₕ₂ calculated based on the above-described Equation 2. At this time, the limit hole angle θₕ₂ may be adjusted by adjusting the diameter d of the through-hole 71b or 71c. In addition, the thickness t of the first plate-shaped member 61a may be adjusted. A plurality of through-holes 71b and 71c are provided in the circumferential direction of the first plate-shaped member 61a. In addition, the through-holes opened to be directed to the side surface of the substrate support 11, such as the through-holes 71b and 71c, mean through-holes that are open so that particles from a partition member (the baffle plate 50) fly to the side surface of the substrate support 11 or a member (e.g., the ring assembly 112 or the like) placed on the outer periphery of the substrate support 11.

The particle region 10s4 in FIG. 11 is the hatched region in FIG. 11. That is, the particle region 10s4 includes a region surrounded by the baffle plate 50, a region to which the particles passing through the space between the first plate-shaped member 61a and the support member 51 fly, and a region to which the particles passing through the through-holes 71b and 71c fly. In addition, the particles passing through the through-holes 71b and 71c in the first plate-shaped member 61a are blocked by the side walls of the shield member 111c and the cover ring 112b. In addition, the particles passing through the space between the first plate-shaped member 61a and the support member 51 are blocked by the second plate-shaped member 62a and the shield member 111c. As a result, particles to be fallen on the substrate W from the baffle plate 50 directly or after a first reflection can be blocked, and the deterioration of exhaust conductance can be suppressed by the through-holes 71b and 71c. In other words, it is possible to suppress the deterioration of exhaust characteristics while implementing a particle shielding rate equivalent to that of a plate-shaped member which is not provided with through-holes. That is, it is possible to suppress the deterioration of exhaust characteristics while suppressing particles generated in the partition member (the baffle plate 50) from flying to the substrate W.

Modifications 1 to 9 of an arrangement of plate-shaped members and through-holes will now be described with reference to FIGS. 12 to 21. In addition, the same components as those of the plasma processing apparatus 1 of the embodiment are denoted by the same reference numerals, and redundant descriptions of the components and operations are omitted. Modifications 1 to 9, which are variations of the through-holes provided in the first plate-shaped member 61 and the second plate-shaped member 62, will be described with reference to drawings similar to FIG. 11.

### [Modification 1]

FIG. 12 is a view illustrating an example of a combination of arrangement of plate-shaped members and through-holes in Modification 1. In Modification 1 of FIG. 12, a case where a first plate-shaped member 61b, which is obtained by providing inclined and vertical through-holes in the first plate-shaped member 61, and a second plate-shaped member 62a, which is not provided with through-holes, will be described.

First, a method of calculating the angles of the through-holes provided in the first plate-shaped member 61b will be described. In Modification 1, the particles passing through the through-holes in the first plate-shaped member 61b are trapped by the second plate-shaped member 62a. In this case, since the through-holes are directed to the side wall 10a of the plasma processing chamber 10, the angles of the through-holes are set to be equal to or less than the limit hole angle θₕ₁. Next, the maximum required shielding angle θₘ, which is the angle of a line interconnecting the position of the through-hole in the first plate-shaped member 61b and the end portion 62b of the second plate-shaped member 62a, is calculated. Regarding the through-hole 71d, the angle of line 80d interconnecting the position of the through-hole 71d and the end portion 62b of the second plate-shaped member 62a is defined as the maximum required shielding angle θₘ and an angle equal to or smaller than the limit hole angle θₕ₁ calculated based on the above-described Equation 1 is set. Similarly, regarding the through-hole 71e, the angle of line 80e interconnecting the position of the through-hole 71e and the end portion 62b of the second plate-shaped member 62a is defined as the maximum required shielding angle θₘ and an angle equal to or smaller than the limit hole angle θₕ₁ calculated based on the above-described Equation 1 is set. At this time, the limit hole angle θₕ₁ may be adjusted by adjusting the diameter d of the through-hole 71d or 71e. In addition, the thickness t of the first plate-shaped member 61b may be adjusted. A plurality of through-holes 71d and 71e are provided in the circumferential direction of the first plate-shaped member 61b. In addition, the through-holes opened to be directed to the inner surface of the plasma processing chamber 10, such as the through-holes 71d and 71e, mean through-holes that are open so that particles from a partition member (the baffle plate 50) fly to the inner surface of the plasma processing chamber 10 or a member (e.g., the second plate-shaped member 62a or the like) placed on the inner surface of the plasma processing chamber 10.

A plurality of vertical through-holes 71f are provided in the radial and circumferential directions of the first plate-shaped member 61b at positions at which the first plate-shaped member 61b on the side wall 10a side overlaps the second plate-shaped member 62a. The range in which the through-holes 71f can be provided is from the end portion of the first plate-shaped member 61b to the portion facing the end portion 62b of the second plate-shaped member 62a. The particles passing through the through-holes 71d, 71e, and 71f in the first plate-shaped member 61b are blocked by the second plate-shaped member 62a. The particle region 10s4 in Modification 1 is the hatched region in FIG. 12. That is, the particle region 10s4 includes a region surrounded by the baffle plate 50, a region to which the particles passing through the space between the first plate-shaped member 61b and the support member 51 fly, and a region to which the particles passing through the through-holes 71d, 71e, and 71f fly. In addition, the particles passing through the space between the first plate-shaped member 61b and the support member 51 are blocked by the second plate-shaped member 62a and the shield member 111c. As a result, particles to be fallen on the substrate W from the baffle plate 50 directly or after a first reflection can be blocked, and the deterioration of exhaust conductance can be further suppressed by the through-holes 71b, 71c, and 71f. That is, it is possible to further suppress the deterioration of exhaust characteristics while suppressing particles generated in the partition member (the baffle plate 50) from flying to the substrate W.

### [Modification 2]

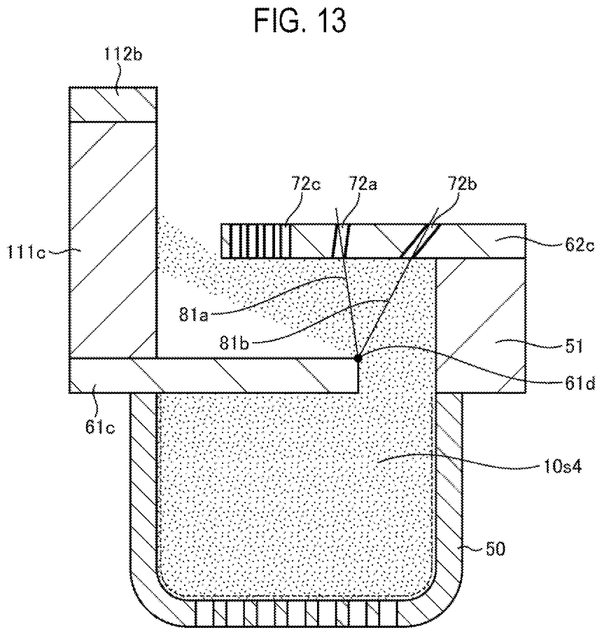

FIG. 13 is a view illustrating an example of a combination of arrangement of plate-shaped members and through-holes in Modification 2. In Modification 2 of FIG. 13, a case where a first plate-shaped member 61c, which is not provided with through-holes, and a second plate-shaped member 62c, which is provided with inclined through-holes and vertical through-holes, are combined will be described.

First, a method of calculating the angles of the through-holes provided in the second plate-shaped member 62c will be described. In Modification 2, the particles passing through the through-holes in the second plate-shaped member 62c are trapped by the peripheral edge of the shower head 13 and the coating film 52. In addition, the particles passing through the through-holes in the second plate-shaped member 62c are particles that have already been reflected one or more times. In this case, since the through-holes are directed to the side wall 10a of the plasma processing chamber 10, the angles of the through-holes are set to be equal to or less than the limit hole angle θₕ₁. Next, the maximum required shielding angle θₘ, which is the angle of a line interconnecting the position of a through-hole in the second plate-shaped member 62c and the end portion 61d of the first plate-shaped member 61c, is calculated. Regarding the through-hole 72a, the angle of line 81a interconnecting the position of the through-hole 72a and the end portion 61d of the first plate-shaped member 61c is defined as the maximum required shielding angle θₘ and is set to an angle equal to or smaller than the limit hole angle θₕ₁ calculated based on the above-described Equation 1. Similarly, regarding the through-hole 72b, the angle of line 81b interconnecting the position of the through-hole 72b and the end portion 61d of the first plate-shaped member 61c is defined as the maximum required shielding angle θₘ and an angle equal to or smaller than the limit hole angle θₕ₁ calculated based on the above-described Equation 1 is set. At this time, the limit hole angle θₕ₁ may be adjusted by adjusting the diameter d of the through-hole 72a or 72b. In addition, the thickness t of the second plate-shaped member 62c may be adjusted. A plurality of through-holes 71a and 72b are provided in the circumferential direction of the second plate-shaped member 62c.

A plurality of vertical through-holes 72c are provided in the radial and circumferential directions of the second plate-shaped member 62c at positions at which the second plate-shaped member 62c on the shield member 111c side overlaps the first plate-shaped member 61c. The range in which the through-holes 72c can be provided is from the end portion of the second plate-shaped member 62c to the portion facing the end portion 61d of the first plate-shaped member 61c. Since the particles passing through the space between the first plate-shaped member 61c and the support member 51 enter the through-holes 72a, 72b, and 72c at an angle larger than the maximum required shielding angle θₘ in the through-holes 72a, 72b, and 72c, the particles are blocked by the second plate-shaped member 62c even if there are through-holes 72a, 72b, and 72c.

The particle region 10s4 in Modification 2 is the hatched region in FIG. 13. That is, the particle region 10s4 includes an area surrounded by the baffle plate 50 and an area to which the particles passing through the space between the first plate-shaped member 61c and the support member 51 fly. In addition, the particles passing through the space between the first plate-shaped member 61c and the support member 51 are blocked by the second plate-shaped member 62c and the shield member 111c. As a result, particles to be fallen on the substrate W from the baffle plate 50 directly or after a first reflection can be blocked, and the deterioration of exhaust conductance can be further suppressed by the through-holes 72a, 72b, and 72c. That is, it is possible to further suppress the deterioration of exhaust characteristics while suppressing particles generated in the partition member (the baffle plate 50) from flying to the substrate W.

### [Modification 3]

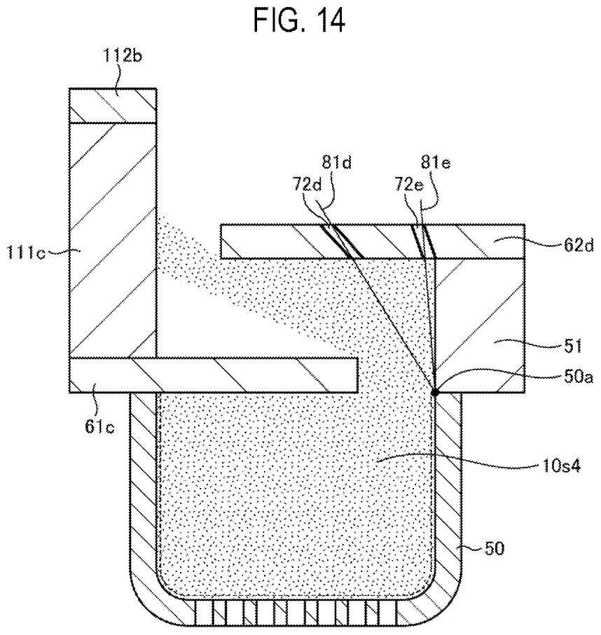

FIG. 14 is a view illustrating an example of a combination of arrangement of plate-shaped members and through-holes in Modification 3. In Modification 3 of FIG. 14, a case where a first plate-shaped member 61c, which is not provided with through-holes, and a second plate-shaped member 62d, which is provided with inclined through-holes, are combined will be described.

First, a method of calculating the angles of the through-holes provided in the second plate-shaped member 62d will be described. In Modification 3, the particles passing through the through-holes in the second plate-shaped member 62d are trapped by the shower head 13. In addition, the particles passing through the through-holes in the second plate-shaped member 62d are particles that have already been reflected one or more times. In this case, since the through-holes are directed to the substrate support 11, the angles of the through-holes are set to be equal to or larger than the limit hole angle θₕ₂. Next, the maximum required shielding angle θₘ, which is the angle of a line interconnecting the position of a through-hole in the second plate-shaped member 62d and the upper end portion 50a of the baffle plate 50, is calculated. Regarding the through-hole 72d, the angle of line 81d interconnecting the position of the through-hole 72d and the upper end portion 50a of the baffle plate 50 is defined as the maximum required shielding angle θₘ and an angle equal to or larger than the limit hole angle θₕ₂ calculated based on the above-described Equation 2 is set. Similarly, regarding the through-hole 72e, the angle of line 81e interconnecting the position of the through-hole 72e and the upper end portion 50a of the baffle plate 50 is defined as the maximum required shielding angle θₘ and an angle equal to or larger than the limit hole angle θₕ₂ calculated based on the above-described Equation 2 is set. At this time, the limit hole angle θₕ₂ may be adjusted by adjusting the diameter d of the through-hole 72d or 72e. In addition, the thickness t of the second plate-shaped member 62d may be adjusted. In addition, a plurality of through-holes 72d and 72e are provided in the circumferential direction of the second plate-shaped member 62d.

Since the particles passing through the space between the first plate-shaped member 61c and the support member 51 enter the through-holes 72d and 72e at an angle smaller than the maximum required shielding angle θₘ in the through-holes 72d and 72e, the particles are blocked by the second plate-shaped member 62d even if there are through-holes 72d and 72e.

The particle region 10s4 in Modification 3 is the hatched region in FIG. 14. That is, the particle region 10s4 includes an area surrounded by the baffle plate 50 and an area to which the particles passing through the space between the first plate-shaped member 61c and the support member 51 fly. In addition, the particles passing through the space between the first plate-shaped member 61c and the support member 51 are blocked by the second plate-shaped member 62d and the shield member 111c. As a result, particles to be fallen on the substrate W from the baffle plate 50 directly or after a first reflection can be blocked, and the deterioration of exhaust conductance can be suppressed by the through-holes 72d and 72e. That is, it is possible to suppress the deterioration of exhaust characteristics while suppressing particles generated in the partition member (the baffle plate 50) from flying to the substrate W.

### [Modification 4]

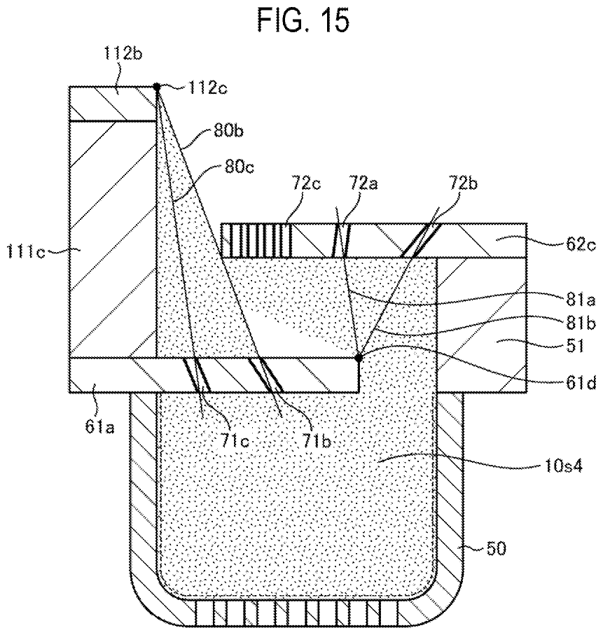

FIG. 15 is a view illustrating an example of a combination of arrangement of plate-shaped members and through-holes in Modification 4. In Modification 4 of FIG. 15, a case where a plate-shaped member 61a, which is obtained by providing through-holes in the first plate-shaped member 61, and a second plate-shaped member 62c, which is obtained by providing inclined through-holes and vertical through-holes in the second plate-shaped member 62, are combined will be described. That is, Modification 4 is a combination of the above-described Example and Modification 2.

Since the method of calculating the angles of the through-holes provided in the first plate-shaped member 61a is the same as Example, the description thereof will be omitted. In addition, since the method of calculating the angles of the through-holes provided in the second plate-shaped member 62c is the same as Modification 2, the description thereof will be omitted. The particles passing through the through-holes 71b and 71c in the first plate-shaped member 61a are blocked by the side walls of the shield member 111c and the cover ring 112b. In addition, since the particles passing through the space between the first plate-shaped member 61c and the support member 51 enter the through-holes 72a, 72b, and 72c at an angle larger than the maximum required shielding angle θₘ in the through-holes 72a, 72b, and 72c, the particles are blocked by the second plate-shaped member 62c even if there are through-holes 72a, 72b, and 72c. When through-holes are provided in both the first plate-shaped member 61 and the second plate-shaped member 62, the diameters d of the through-holes may be the same, or the diameter in one of the plate-shaped members may be made small and the diameter in the other may be made large. That is, when the diameter d in one of the plate-shaped members is made small, the diameter d in the other plate-shaped member can be made larger.

The particle region 10s4 in Modification 4 is the hatched region in FIG. 15. That is, the particle region 10s4 includes a region surrounded by the baffle plate 50, a region to which the particles passing through the space between the first plate-shaped member 61a and the support member 51 fly, and a region to which the particles passing through the through-holes 71b and 71c fly. As a result, particles to be fallen on the substrate W from the baffle plate 50 directly or after a first reflection can be blocked, and the deterioration of exhaust conductance can be further suppressed by the through-holes 71b, 71c, 72a, 72b, and 72c. That is, it is possible to further suppress the deterioration of exhaust characteristics while suppressing particles generated in the partition member (the baffle plate 50) from flying to the substrate W.

### [Modification 5]

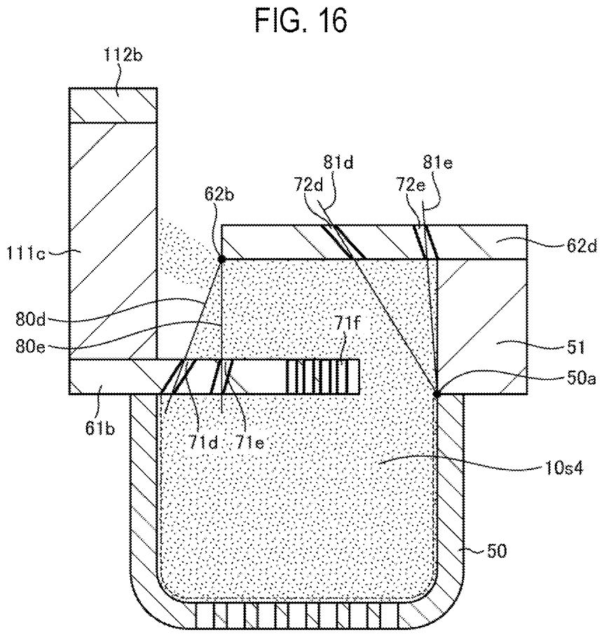

FIG. 16 is a view illustrating an example of a combination of arrangement of plate-shaped members and through-holes in Modification 5. In Modification 5 of FIG. 16, a case where a first plate-shaped member 61b, which is obtained by providing inclined through-holes and vertical through-holes in the first plate-shaped member 61, and a second plate-shaped member 62d, which is obtained by providing inclined through-holes in the second plate-shaped member 62, are combined will be described. That is, Modification 5 is a combination of the above-described Modification 1 and Modification 3.

Since the method of calculating the angles of the through-holes provided in the first plate-shaped member 61b is the same as Modification 1, the description thereof will be omitted. In addition, since the method of calculating the angles of the through-holes provided in the second plate-shaped member 62d is the same as Modification 3, the description thereof will be omitted. The particles passing through the through-holes 71d, 71e, and 71f in the first plate-shaped member 61b are blocked by the second plate-shaped member 62d. In addition, since particles passing through the space between the first plate-shaped member 61b and the support member 51 enter the through-holes 72d and 72e at an angle smaller than the maximum required shielding angle θₘ in the through-holes 72d and 72e, the particles are blocked by the second plate-shaped member 62d even if there are through-holes 72d and 72e.

The particle region 10s4 in Modification 5 is the hatched region in FIG. 16. That is, the particle region 10s4 includes a region surrounded by the baffle plate 50, a region to which the particles passing through the space between the first plate-shaped member 61b and the support member 51 fly, and a region to which the particles passing through the through-holes 71d, 71e, and 71f fly. In addition, the particles passing through the space between the first plate-shaped member 61b and the support member 51 are blocked by the second plate-shaped member 62d and the shield member 111c. As a result, particles to be fallen on the substrate W from the baffle plate 50 directly or after a first reflection can be blocked, and the deterioration of exhaust conductance can be further suppressed by the through-holes 71d, 71e, 71f, 72d, and 72e. That is, it is possible to further suppress the deterioration of exhaust characteristics while suppressing particles generated in the partition member (the baffle plate 50) from flying to the substrate W.

### [Modification 6]

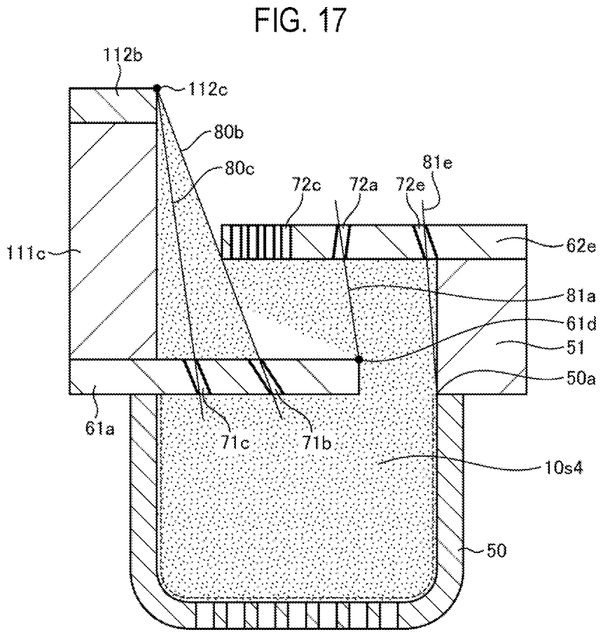

FIG. 17 is a view illustrating an example of a combination of arrangement of plate-shaped members and through-holes in Modification 6. In Modification 6 of FIG. 17, a case where a first plate-shaped member 61a, which is obtained by providing through-holes in the first plate-shaped member 61, and a second plate-shaped member 62e, which is obtained by providing inclined through-holes in different orientations and vertical through-holes in the second plate-shaped member 62, are combined will be described. That is, Modification 6 is a combination of the above-described Example, Modification 2, and Modification 3.

Since the method of calculating the angles of the through-holes provided in the first plate-shaped member 61a is the same as Example, the description thereof will be omitted. In addition, since the method of calculating the angles of the through-holes provided in the second plate-shaped member 62e is the same as Modifications 2 and 3, the description thereof will be omitted. The particles passing through the through-holes 71b and 71c in the first plate-shaped member 61a are blocked by the side walls of the shield member 111c and the cover ring 112b. In addition, since the particles passing through the space between the first plate-shaped member 61a and the support member 51 enter the through-holes 72a, 72c, and 72e at an angle larger or smaller than the maximum required shielding angle θₘ in the through-holes 72a, 72c, and 72e, the particles are blocked by the second plate-shaped member 62e even if there are through-holes 72a, 72c, and 72e.

The particle region 10s4 in Modification 6 is the hatched region in FIG. 17. That is, the particle region 10s4 includes a region surrounded by the baffle plate 50, a region to which the particles passing through the space between the first plate-shaped member 61a and the support member 51 fly, and a region to which the particles passing through the through-holes 71b and 71c fly. In addition, the particles passing through the space between the first plate-shaped member 61a and the support member 51 are blocked by the second plate-shaped member 62e and the shield member 111c. As a result, particles to be fallen on the substrate W from the baffle plate 50 directly or after a first reflection can be blocked, and the deterioration of exhaust conductance can be further suppressed by the through-holes 71b, 71c, 72a, 72c, and 72e. That is, it is possible to further suppress the deterioration of exhaust characteristics while suppressing particles generated in the partition member (the baffle plate 50) from flying to the substrate W.

### [Modification 7]

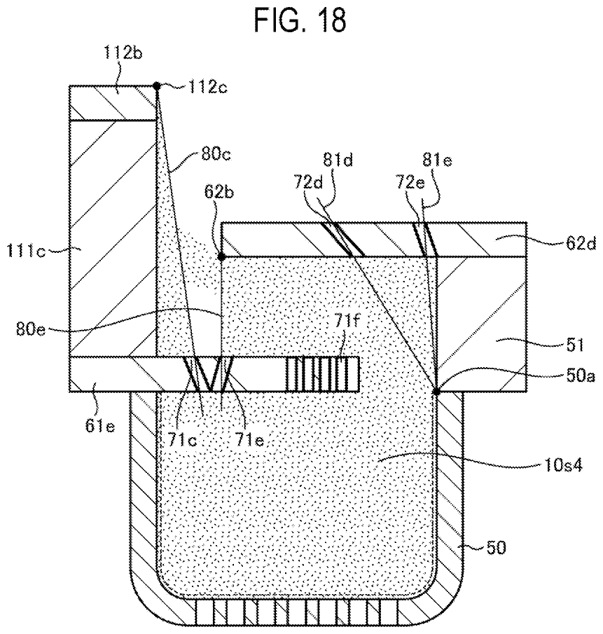

FIG. 18 is a view illustrating an example of a combination of arrangement of plate-shaped members and through-holes in Modification 7. In Modification 7 of FIG. 18, a case where a first plate-shaped member 61e, which is obtained by providing inclined through-holes in different orientations and vertical through-holes in the first plate-shaped member 61, and a second plate-shaped member 62d, which is obtained by providing inclined through-holes in the second plate-shaped member 62, are combined will be described. That is, Modification 7 is a combination of the above-described Example, Modification 1, and Modification 3.

Since the method of calculating the angles of the through-holes provided in the first plate-shaped member 61e is the same as Embodiment and Modification 1, the description thereof will be omitted. In addition, since the method of calculating the angles of the through-holes provided in the second plate-shaped member 62d is the same as Modification 3, the description thereof will be omitted. The particles passing through the through-hole 71c in the first plate-shaped member 61e are blocked by the side walls of the shield member 111c and the cover ring 112b. In addition, the particles passing through the through-holes 71e and 71f in the first plate-shaped member 61e are blocked by the second plate-shaped member 62d. In addition, since particles passing through the space between the first plate-shaped member 61e and the support member 51 enter the through-holes 72d and 72e at an angle smaller than the maximum required shielding angle θₘ in the through-holes 72d and 72e, the particles are blocked by the second plate-shaped member 62d even if there are through-holes 72d and 72e.

The particle region 10s4 in Modification 7 is the hatched region in FIG. 18. That is, the particle region 10s4 includes a region surrounded by the baffle plate 50, a region to which the particles passing through the space between the first plate-shaped member 61e and the support member 51 fly, and a region to which the particles passing through the through-holes 71c and 71e fly. In addition, the particles passing through the space between the first plate-shaped member 61e and the support member 51 are blocked by the second plate-shaped member 62d and the shield member 111c. As a result, particles to be fallen on the substrate W from the baffle plate 50 directly or after a first reflection can be blocked, and the deterioration of exhaust conductance can be further suppressed by the through-holes 71c, 71e, 71f, 72d, and 72e. That is, it is possible to further suppress the deterioration of exhaust characteristics while suppressing particles generated in the partition member (the baffle plate 50) from flying to the substrate W.

### [Modification 8]

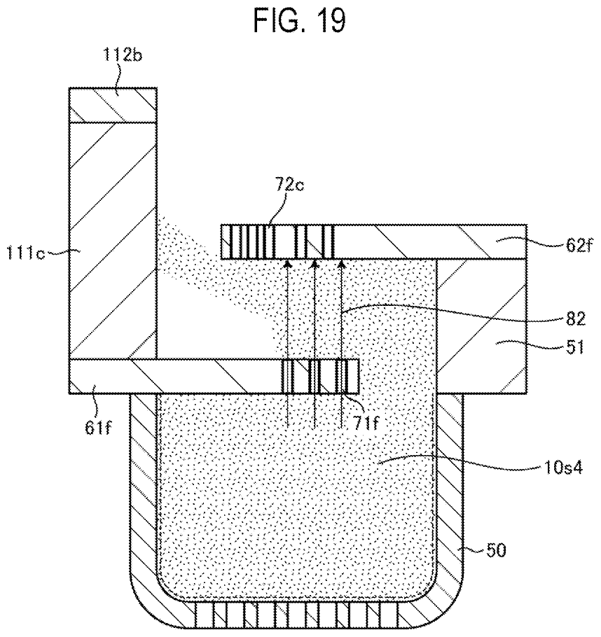

FIG. 19 is a view illustrating an example of a combination of arrangement of plate-shaped members and through-holes in Modification 8. In Modification 8 of FIG. 19, a case where a first plate-shaped member 61f, which is obtained by providing vertical through-holes in the first plate-shaped member 61, and a second plate-shaped member 62f, which is obtained by providing vertical through-holes in the second plate-shaped member 62, are combined will be described. That is, Modification 8 is a combination of the above-described through-holes 71f of Modification 1 and through-holes 72c of Modification 2.

In Modification 8, a plurality of through-holes 71f in the first plate-shaped member 61f and a plurality of through-holes 72c in the second plate-shaped member 62f are provided in the radial directions and the circumferential directions of the first plate-shaped member 61f and the second plate-shaped member 62f such that they do not overlap each other when viewed in the vertical direction (in plan view). That is, the flight paths 82 of the particles passing through the through-holes 71f are blocked at places other than the through-holes 72c in the second plate-shaped member 62f. In addition, since the particles obliquely passing through the through-holes 71f enter the through-holes 72c at an angle smaller or larger than the maximum required shielding angle θₘ in the through-holes 72c, the particles are blocked by the second plate-shaped member 62f even if there are the through-holes 72c.

The particle region 10s4 in Modification 8 is the hatched region in FIG. 19. That is, the particle region 10s4 includes a region surrounded by the baffle plate 50, a region to which the particles passing through the space between the first plate-shaped member 61f and the support member 51 fly, and a region to which the particles passing through the through-holes 71f fly. In addition, the particles passing through the space between the first plate-shaped member 61f and the support member 51 are blocked by the second plate-shaped member 62f and the shield member 111c. As a result, particles to be fallen on the substrate W from the baffle plate 50 directly or after a first reflection can be blocked, and the deterioration of exhaust conductance can be further suppressed by the through-holes 71f and 72c. That is, it is possible to further suppress the deterioration of exhaust characteristics while suppressing particles generated in the partition member (the baffle plate 50) from flying to the substrate W.

### [Modification 9]

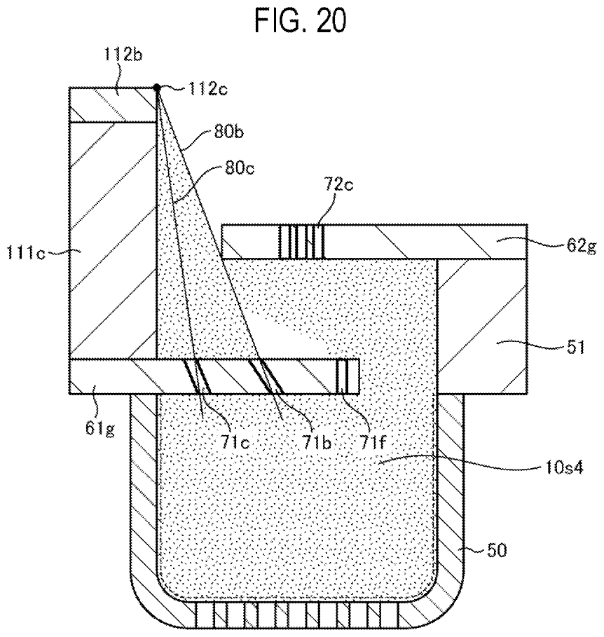

FIG. 20 is a view illustrating an example of a combination of arrangement of plate-shaped members and through-holes in Modification 9. In Modification 9 of FIG. 20, a case where a first plate-shaped member 61g, which is obtained by providing inclined through-holes and vertical through-holes in the first plate-shaped member 61, and a second plate-shaped member 62g, which is obtained by providing vertical through-holes in the second plate-shaped member 62, are combined will be described. That is, Modification 9 is a combination of the above-described Embodiment, some of the through-holes 71f of Modification 1, and some of the through-holes 72c of Modification 2.

Since the method of calculating the angles of the inclined through-holes provided in the first plate-shaped member 61g is the same as Example, the description thereof will be omitted. In addition, the particles passing through the through-holes 71b and 71c in the first plate-shaped member 61g are blocked by the side walls of the shield member 111c and the cover ring 112b.

FIG. 21 is a view illustrating an example of an arrangement of through-holes in Modification 9 when viewed in a vertical direction. In addition, FIG. 21 illustrates the overlapping portions of the first plate-shaped member 61g and the second plate-shaped member 62g in the state of being arranged vertically. As illustrated in FIG. 21, in Modification 9, the upper end openings of a plurality of through-holes 71b and 71c and a plurality of through-holes 71f in the first plate-shaped member 61g and the plurality of through-holes 72c in the second plate-shaped member 62g are provided in the circumferential directions of the first plate-shaped member 61g and the second plate-shaped member 62g such that they do not overlap each other in plan view. In addition, the plurality of through-holes 72c are also provided in the radial direction of the second plate-shaped member 62g.

In addition, by providing through-holes 71b, 71c, and 71f and the through-holes 72c, each of which has a diameter of 5 mm, in the first plate-shaped member 61g and the second plate-shaped member 62g, conductance can be increased, for example, 1.6 to 1.7 times compared with the case where no through-holes are provided.

In Modification 9, the particles passing through the through-holes 71f are blocked at places other than the through-holes 72c in the second plate-shaped member 62g. In addition, since the particles obliquely passing through the through-holes 71f enter the through-holes 72c at an angle larger than the maximum required shielding angle θₘ in the through-holes 72c, the particles are blocked by the second plate-shaped member 62g even if there are the through-holes 72c.

The particle region 10s4 in Modification 9 is the hatched region in FIG. 20. That is, the particle region 10s4 includes a region surrounded by the baffle plate 50, a region to which the particles passing through the space between the first plate-shaped member 61g and the support member 51 fly, and a region to which the particles passing through the through-holes 71b, 71c, and 71f fly. In addition, the particles passing through the space between the first plate-shaped member 61g and the support member 51 are blocked by the second plate-shaped member 62g and the shield member 111c. As a result, particles to be fallen on the substrate W from the baffle plate 50 directly or after a first reflection can be blocked, and the deterioration of exhaust conductance can be further suppressed by the through-holes 71b, 71c, 71f, and 72c. That is, it is possible to further suppress the deterioration of exhaust characteristics while suppressing particles generated in the partition member (the baffle plate 50) from flying to the substrate W.

In addition, although the first plate-shaped member 61 and the second plate-shaped member 62 are used as the plate-shaped members in the above-described Example and each Modification, the present disclosure is not limited thereto. For example, as long as the amount of particles in the region 10s1 illustrated in FIG. 3 can be suppressed to an allowable amount, the number of plate-shaped members may be one. This may make it possible to further suppress the deterioration of exhaust characteristics compared with the case where two plate-shaped members are provided. In addition, when using one plate-shaped member, the gap provided between the substrate support 11 and the side wall 10a may be eliminated. Furthermore, the number of plate-shaped members may be three or more. This may make it possible to suppress particles from flying to the substrate W by two or more reflections.

As described above, according to the present embodiment, a substrate processing apparatus (the plasma processing apparatus 1) includes a chamber (the plasma processing chamber 10) including an exhaust port (the gas discharge port 10e) in a bottom portion thereof; a substrate support 11 disposed within the chamber; a partition member (the baffle plate 50) that partitions a substrate processing region (the plasma processing space 10s) from an exhaust region connected to the exhaust port, one or more plate-shaped members (the first plate-shaped member 61) provided upstream of the partition member with respect to a flow of exhaust gas to the exhaust port and configured to block particles from the partition member, wherein at least one of the one or more plate-shaped members includes a through-hole configured to allow the exhaust gas to the exhaust port to pass therethrough, the through-hole opened to be directed to a side surface of the substrate support or to an inner surface of the chamber. As a result, it is possible to suppress the deterioration of exhaust characteristics while suppressing particles generated in the partition member from flying to the substrate W.

According to the present embodiment, in the chamber, the exhaust port is provided at a position lower than a support surface (the central region 111a) of the substrate support 11 on which a substrate W is supported, around the substrate support 11, the partition member is arranged upstream of the exhaust port with respect to the flow of the exhaust gas to the exhaust port, around the substrate support 11, and the one or more plate-shaped members are arranged upstream of the partition member with respect to the flow of the exhaust gas to the exhaust port, around the substrate support 11. As a result, it is possible to suppress the deterioration of exhaust characteristics while suppressing particles generated in the partition member from flying to the substrate W.

According to the present embodiment and Modifications 4, 6, 7, and 9, the through-holes 71b and 71c are provided in the at least one of the one or more plate-shaped members to open to be directed to a ring member (the cover ring 112b) disposed around the substrate W. As a result, it is possible to further suppress the deterioration of exhaust characteristics while suppressing particles generated in the partition member from flying to the substrate W.

According to the present embodiment and Modifications 4, 6, 7, and 9, the one or more plate-shaped members include a first plate-shaped member 61a, 61e, or 61g provided upstream of the partition member with respect to the flow of the exhaust gas to the exhaust port, around the substrate support 11 and, and a second plate-shaped member 62a, 62c, 62d, 62e, or 62g provided upstream of the first plate-shaped member, and the through-holes 71b and 71c are provided in the first plate-shaped member to open to be directed to the ring member. As a result, it is possible to suppress the deterioration of exhaust characteristics while suppressing particles generated in the partition member from flying to the substrate W.

According to Modifications 1, 5, and 7, the one or more plate-shaped members include a first plate-shaped member 61b or 61e provided around the substrate support 11 and upstream of the partition member with respect to the flow of the exhaust gas to the exhaust port, and a second plate-shaped member 62a or 62d provided upstream of the first plate-shaped member, and the through-holes 71d and 71e are provided in the first plate-shaped member to open to be directed to the second plate-shaped member. As a result, particles generated in the partition member can be directed away from the substrate W.

According to Modifications 5 and 7, the through-holes are provided in the second plate-shaped member 62d to open to be directed to another member (the shower head 13) located in the substrate processing region (through-holes 72d and 72e) while being provided in the first plate-shaped member 61b or 61e to open to be directed to the second plate-shaped member 62d (the through-holes 71d and 71e). As a result, particles generated in the partition member can be reflected multiple times by the members inside the plasma processing chamber 10 to reduce the flying speed of the particles.

According to Modifications 1, 5, and 7, the through-holes provided in the first plate-shaped member 61b or 61e include first through-holes 71d and 71e, each of which has an inclination equal to or smaller than an angle θₕ₁ based on an angle θₘ₁ formed between the first plate-shaped member and a line 80d or 80e interconnecting an end portion 62b of the second plate-shaped member 62a or 62d and a position of the through-hole in the first plate-shaped member, the thickness of the first plate-shaped member, and the diameter of the through-hole. As a result, the particles passing through the first through-holes can be blocked by the second plate-shaped member.

According to Modifications 1, 5, and 7, the angle θₕ₁ is calculated by the Equation 3 shown in FIG. 24, wherein t is the thickness of the first plate-shaped member 61b or 61e, d is the diameter of the through-hole 71d or 71e, and θₘ₁ is the angle formed between the first plate-shaped member and the line 80d or 80e interconnecting the end portion of the second plate-shaped member 62a or 62d and the position of the through-hole in the first plate-shaped member. As a result, the particles passing through the first through-holes can be blocked by the second plate-shaped member.

According to the present embodiment and Modifications 4, 6, 7, and 9, the through-holes provided in the first plate-shaped member 61a, 61e, or 61g include second through-holes 71b and 71c, each of which has an inclination equal to or larger than an angle θₕ₂ based on an angle θₘ₂ formed between the first plate-shaped member and a line 80b or 80c interconnecting an upper end portion 112c of the side surface of the substrate support 11 and the position of the through-hole in the first plate-shaped member, the thickness of the first plate-shaped member, and the diameter of the through-hole. As a result, the particles passing through the second through-holes can be blocked by the side surface of the substrate support 11.

According to the present embodiment and Modifications 4, 6, 7, and 9, the angle θₕ₂ is calculated by the Equation 4 shown in FIG. 25, wherein t is the thickness of the first plate-shaped member 61a, 61e, or 61g, d is the diameter of the through-hole 71b or 71c, and θₘ₂ is the angle formed between the first plate-shaped member and the line 80b or 80c interconnecting the upper end portion 112c of the side surface of the substrate support 11 and the position of the through-hole in the first plate-shaped member.

According to Modifications 1, 2, 4 to 9, the through-holes include third through-holes 71f and 72c that open perpendicularly to planar directions of the one or more plate-shaped members. As a result, it is possible to further suppress the deterioration of exhaust characteristics while suppressing particles generated in the partition member from flying to the substrate W.

According to Modifications 4 to 7, the through-holes 71b, 71c, 72d, and 72e open at positions that do not overlap each other in plan view of the first plate-shaped member 61a, 61b, or 61e and the second plate-shaped member 62c, 62d, or 62e. As a result, it is possible to prevent particles passing through the through-holes in the first plate-shaped member from passing through the through-holes in the second plate-shaped member.

It should be considered that the embodiment and each modification disclosed herein are exemplary in all respects and are not restrictive. Various omissions, substitutions, and changes may be made to the above-described embodiment and each modification without departing from the scope and spirit of the appended claims.

In addition, in the above-described embodiment and each modification, circular through-holes have been described as the through-holes provided in the first plate-shaped member 61 and the second plate-shaped member 62, but the present disclosure is not limited thereto. For example, the through-holes may have a square or triangular cross section.

Furthermore, the through-holes may be tapered such that the lower portions of the through-holes become wider.

According to the present disclosure, it is possible to suppress the deterioration of exhaust characteristics while suppressing particles generated in a partition member from flying to a substrate W.

In addition, the present disclosure may also take the following configurations. (1) A substrate processing apparatus includes: a chamber including an exhaust port in a bottom portion of the chamber; a substrate support disposed within the chamber; a partition member that partitions a substrate processing region from an exhaust region connected to the exhaust port; one or more plate-shaped members provided upstream of the partition member with respect to a flow of exhaust gas to the exhaust port and configured to block particles from the partition member, wherein at least one of the one or more plate-shaped members includes a through-hole configured to allow the exhaust gas to the exhaust port to pass therethrough, the through-hole opened to be directed to a side surface of the substrate support or to an inner surface of the chamber.

(2) The substrate processing apparatus set forth in the item (1), wherein, in the chamber, the exhaust port is provided at a position lower than a support surface of the substrate support on which a substrate is supported, around the substrate support, the partition member is arranged upstream of the exhaust port with respect to the flow of the exhaust gas to the exhaust port, around the substrate support, and the one or more plate-shaped members are arranged upstream of the partition member with respect to the flow of the exhaust gas to the exhaust port, around the substrate support.

(3) The substrate processing apparatus set forth in the item (2), wherein the through-hole is provided in the at least one of the one or more plate-shaped members to open to be directed to a ring member disposed around the substrate.

(4) The substrate processing apparatus set forth in the item (3), wherein the one or more plate-shaped members include a first plate-shaped member provided upstream of the partition member with respect to the flow of the exhaust gas to the exhaust port, around the substrate support, and a second plate-shaped member provided upstream of the first plate-shaped member, and the through-hole is provided in the first plate-shaped member to open to be directed to the ring member.

(5) The substrate processing apparatus of any one of items (2) to (4), wherein the one or more plate-shaped members include a first plate-shaped member provided upstream of the partition member with respect to the flow of the exhaust gas to the exhaust port, around the substrate support, and a second plate-shaped member provided upstream of the first plate-shaped member, and the through-hole is provided in the first plate-shaped member to open to be directed to the second plate-shaped member.

(6) The substrate processing apparatus set forth in the item (5), wherein the through-hole is provided in the second plate-shaped member to open to be directed to another member located in the substrate processing region as well as being provided in the first plate-shaped member to open to be directed to the second plate-shaped member.

(7) The substrate processing apparatus set forth in the item (5), wherein the through-hole provided in the first plate-shaped member includes a first through-hole, which has an inclination equal to or smaller than an angle θₕ₁ based on an angle θₘ₁ formed between the first plate-shaped member and a line interconnecting an end portion of the second plate-shaped member and the position of the through-hole in the first plate-shaped member, the thickness of the first plate-shaped member, and the diameter of the through-hole.

(8) The substrate processing apparatus set forth in the item (7), wherein the angle θₕ₁ is calculated by the Equation 3 shown in FIG. 24, wherein t is the thickness of the first plate-shaped member, d is the diameter of the through-hole, and θₘ₁ is the angle formed between the first plate-shaped member and the line interconnecting the end portion of the second plate-shaped member and the position of the through-hole in the first plate-shaped member.

(9) The substrate processing apparatus of any one of items (4) to (8), wherein the through-hole provided in the first plate-shaped member include a second through-hole, which has an inclination equal to or larger than an angle θₕ₂ based on an angle θₘ₂ formed between the first plate-shaped member and a line interconnecting an upper end portion of the side surface of the substrate support and the position of the through-hole in the first plate-shaped member.

(10) The substrate processing apparatus set forth in the item (9), wherein the angle θₕ₂ is calculated by the Equation 4 shown in FIG. 25, wherein t is the thickness of the first plate-shaped member, d is the diameter of the through-hole, and θₘ₂ is the angle formed between the first plate-shaped member and the line interconnecting the upper end portion of the side surface of the substrate support and the position of the through-hole in the first plate-shaped member.

(11) The substrate processing apparatus of any one of items (1) to (10), wherein the through-hole includes a third through-hole that opens perpendicularly to each of planar directions of the one or more plate-shaped members.

(12) The substrate processing apparatus of any one of items (4) to (10), wherein the through-hole opens at each of positions that do not overlap each other in plan view of the first plate-shaped member and the second plate-shaped member.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a chamber comprising an exhaust port in a bottom portion of the chamber;
a substrate support disposed within the chamber;
a partition member that partitions a substrate processing region from an exhaust region connected to the exhaust port;
one or more plate-shaped members provided upstream of the partition member with respect to a flow of exhaust gas to the exhaust port and configured to block particles from the partition member,
wherein at least one of the one or more plate-shaped members comprises a through-hole configured to allow the exhaust gas to the exhaust port to pass therethrough, the through-hole opened to be directed to a side surface of the substrate support or to an inner surface of the chamber.

2. The substrate processing apparatus of claim 1, wherein, in the chamber, the exhaust port is provided at a position lower than a support surface of the substrate support on which a substrate is supported, around the substrate support,
the partition member is arranged upstream of the exhaust port with respect to the flow of the exhaust gas to the exhaust port, around the substrate support, and
the one or more plate-shaped members are arranged upstream of the partition member with respect to the flow of the exhaust gas to the exhaust port, around the substrate support.

3. The substrate processing apparatus of claim 2, wherein the through-hole is provided in the at least one of the one or more plate-shaped members to open to be directed to a ring member disposed around the substrate.

4. The substrate processing apparatus of claim 3, wherein the one or more plate-shaped members comprises a first plate-shaped member provided upstream of the partition member with respect to the flow of the exhaust gas to the exhaust port, around the substrate support, and a second plate-shaped member provided upstream of the first plate-shaped member, and
the through-hole is provided in the first plate-shaped member to open to be directed to the ring member.

5. The substrate processing apparatus of claim 2, wherein the one or more plate-shaped members comprises a first plate-shaped member provided upstream of the partition member with respect to the flow of the exhaust gas to the exhaust port, around the substrate support, and a second plate-shaped member provided upstream of the first plate-shaped member, and
the through-hole is provided in the first plate-shaped member to open to be directed to the second plate-shaped member.

6. The substrate processing apparatus of claim 5, wherein the through-hole is provided in the first plate-shaped member to open to be directed to the second plate-shaped member, and is provided in the second plate-shaped member to open to be directed to another member located in the substrate processing region.

7. The substrate processing apparatus of claim 5, wherein the through-hole provided in the first plate-shaped member include a first through-hole, which has an inclination equal to or smaller than an angle θₕ₁ based on an angle θₘ₁ formed between the first plate-shaped member and a line interconnecting an end portion of the second plate-shaped member and a position of the through-hole in the first plate-shaped member, a thickness of the first plate-shaped member, and a diameter of the through-hole in the first plate-shaped member.

8. The substrate processing apparatus of claim 7, wherein the angle θₕ₁ is calculated by Equation 1, wherein t is the thickness of the first plate-shaped member, d is the diameter of the through-hole, and θₘ₁ is the angle formed between the first plate-shaped member and the line interconnecting the end portion of the second plate-shaped member and the position of the through-hole in the first plate-shaped member.
$$[ Equation 1 ]$$
$${θ}_{h 1} = {Tan}^{- 1} [ \frac{t}{d + t \times tan ( {θ}_{m 1} - \frac{π}{2} )} ] \qquad ( 1 )$$

9. The substrate processing apparatus of claim 4, wherein the through-hole provided in the first plate-shaped member comprises a second through-hole, which has an inclination equal to or larger than an angle θₕ₂ based on an angle θₘ₂ formed between the first plate-shaped member and a line interconnecting an upper end portion of the side surface of the substrate support and a position of the through-hole in the first plate-shaped member, a thickness of the first plate-shaped member, and a diameter of the through-hole.

10. The substrate processing apparatus of claim 9, wherein the angle θₕ₂ is calculated by Equation 2, wherein t is the thickness of the first plate-shaped member, d is the diameter of the through-hole, and θₘ₂ is the angle formed between the first plate-shaped member and the line interconnecting the upper end portion of the side surface of the substrate support and the position of the through-hole in the first plate-shaped member.
$$[ Equation 2 ]$$
$${θ}_{h 2} = \frac{π}{2} + {Tan}^{- 1} [ \frac{d}{t} - tan ( \frac{π}{2} - {θ}_{m 2} ) ] \qquad ( 2 )$$

11. The substrate processing apparatus of claim 1, wherein the through-hole comprises a third through-hole that opens perpendicularly to a planar direction of each of the one or more plate-shaped members.

12. The substrate processing apparatus of claim 4, wherein the through-hole opens at each of positions that do not overlap each other in plan view of the first plate-shaped member and the second plate-shaped member.

13. The substrate processing apparatus of claim 5, wherein the through-hole opens at each of positions that do not overlap each other in plan view of the first plate-shaped member and the second plate-shaped member.
